(19) United States
(12) Patent Application Publication
(10) Pub. No.: US 2006/0170447 A1
(43) Pub. Date: Aug. 3, 2006

(54) Electronics device, optical panel, inspection probe, inspection device for the optical panel and inspection method for the optical panel

(75) Inventors: Akitoshi Maeda, Shiojiri (JP); Eiichi Yamagishi, Shiojiri (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/344,837

(22) Filed: Feb. 1, 2006

(30) Foreign Application Priority Data
Feb. 2, 2005 (JP) 2005-026972
Feb. 2, 2005 (JP) 2005-026974
Nov. 9, 2005 (JP) 2005-325010

(51) Int. Cl. G01R 31/00

(52) U.S. Cl. 324/770

(57) ABSTRACT

An electronics device includes: a plurality of signal lines; and a drawing portion to which the plurality of signal lines are drawn to be disposed substantially in parallel with each other, in which the drawing portion has an inspection terminal allocating layer in which predetermined ones out of the signal lines are insulatively covered in a direction intersecting the drawing direction of the signal lines, while other predetermined ones out of the signal lines that are not insulatively covered are exposed as an inspection signal input terminal.

The entire disclosure of Japanese Patent Application No. 2005-325010, filed Nov. 9, 2005, is expressly incorporated by reference herein.

### BACKGROUND

1. Technical Field

The present invention relates to an electronics device, an optical panel, an inspection probe, an inspection device for the optical panel and an inspection method for the optical panel.

2. Related Art

There have been known liquid crystal display panels as an optical panel for displaying an image, and a display device having such a liquid crystal display panel as stated and a drive circuit that drives the liquid crystal display panel.

FIG. 17 shows a structure of a display device 10 of a related art.

The liquid crystal display panel 20 has liquid crystal cells (not shown) respectively provided to each of pixels on a display surface, thin-film two-terminal elements (switching elements) (not shown) respectively provided to the liquid crystal cells, a plurality of scanning lines 21 respectively wired on rows of the liquid crystal display panel and a plurality of data lines 22 respectively wired on columns of the liquid crystal display panel 20.

The plurality of data lines 22 and scanning lines 21 are drawn out from the liquid crystal display panel 20 and collectively arranged to a side 31 of a substrate 30.

In FIG. 17, the plurality of data lines 22 are collectively wired substantially in the middle of the side 31 of the substrate 30. Odd scanning lines 21A are arranged on the right of the data lines 22, while even scanning lines 21B are arranged on the left of the data lines 22.

The drive circuit 40 has a scanning line driver (not shown) that sends the scanning lines 21 with a scanning signal that sequentially selects a scanning line 21 and a data line driver (not shown) that sends data signals of the respective pixels on the selected scanning line 21 to the corresponding data lines 22.

Input connector terminals 32 for signal input are provided for the data lines 22 and scanning lines 21 that are arranged to the side 31 of the substrate 30, while output connector terminals 41 for signal output are provided for the drive circuit 40.

The output connector terminals 41 are connected with the input connector terminals 32, so that the signals are applied from the drive circuit 40 to the data lines 22 and scanning lines 21. Thereby, an image is displayed on the liquid crystal display panel 20.

Recently, the number of pixels of the liquid crystal display panel 20 has been remarkably increased in order to display a fine image. Along with the increase, a distance between the scanning lines 21 or between the data lines 22 has become smaller and smaller.

In the above-described liquid crystal display panel, an image display inspection is conducted for a defect such as an electricity leakage caused by a short between signal lines (data lines 22, scanning lines 21), which normally should be insulated from each other (see, for example, JP-A-2003-66870).

In the image display inspection, an inspection probe 50 is used for sending image inspection signals to the scanning lines 21 and data lines 22, the inspection probe 50 being temporarily connected to the data lines 22 and scanning lines 21. The inspection signals are then applied to the data lines 22 and scanning lines 21 via the inspection probe 50. Thereby, whether the liquid crystal display panel 20 is properly lighted is checked.

FIG. 18 is an enlarged view showing a connecting portion of the inspection probe 50 and the data lines 22.

As is obvious, the inspection probe 50 has probe terminals 51 to be connected with terminals 23 of the scanning lines 21 and data lines 22, and when connecting the inspection probe 50 with the scanning lines 21 and data lines 22, each probe terminal 51 of the inspection probe 50 is to be precisely positioned and then connected with the terminal 23 of the scanning lines 21 and data lines 22, as shown in FIG. 18.

In recent years, the liquid crystal display panel 20 that can display a fine image while being compact is demanded, which means that so many pixels need to be arrayed in a small area.

Hence, the distance between the signal lines (scanning lines 21, data lines 22) becomes extremely small. For example, a few hundreds of signal lines are aligned with a pitch of 21 μm.

When the signal lines are aligned with such a small pitch, the terminals of the inspection probe 50 to be connected with the signal lines also needs to have an extremely small pitch.

However, manufacturing the inspection probe 50 having such a small terminal pitch requires a considerable number of processing steps and a huge cost.

In addition, precisely positioning the terminals with a small pitch (e.g., 21 μm) and respectively connecting with corresponding terminals are highly difficult, which can be carried, for example, by checking on a monitor an image picked by a CCD camera.

Preparing a positioning device with a camera and a monitor also requires a large cost, and the connection work takes a lot of time.

The high cost in the image display inspection of the liquid crystal display panel expands the production cost, while prolonged time for the image display inspection reduces the manufacturing efficiency.

### SUMMARY

An object of the invention is to provide an electronics device, an optical panel, an inspection probe, an inspection device for the optical panel and an inspection method for the optical panel for an easy image display inspection.

An electronics device according to an aspect of the invention includes: a plurality of signal lines; and a drawing portion to which the plurality of signal lines are drawn to be disposed substantially in parallel with each other, in which the drawing portion has an inspection terminal allocating layer in which predetermined ones out of the signal lines are insulatively covered in a direction intersecting the drawing direction of the signal lines, while other predetermined ones out of the signal lines that are not insulatively covered are exposed as an inspection signal input terminal.

In the arrangement, where the plurality of signal lines can be input with a common inspection signal in the inspection, a connection with predetermined signal lines can be established only by pressing a common wiring to the inspection terminal allocating layer, since the plurality of predetermined signal lines to which the common inspection signal can be input are exposed as a signal input terminal in the inspection terminal allocating layer.

Thus, it is only necessary to press the wiring on the inspection terminal allocating layer, so that the connection work between the signal lines and the inspection probe is extremely simple.

Preferably, the inspection terminal allocating layers are arranged in the drawing direction of the signal lines. Further, where each inspection terminal allocating layer has the predetermined signal lines being exposed as a signal input terminal, when focusing on each signal line, all the signal lines are preferably exposed in one of the inspection terminal allocating layers.

According to the arrangement, continuity can be established with all the signal lines by pressing the wiring of the inspection probe to all the inspection terminal allocating layers.

An optical panel according to an aspect of the invention has: columns of pixels exhibiting common one of basic colors, the columns of pixels exhibiting different basic colors being arranged in a row direction in a predetermined order so that more than one basic color are used to display a color image; and a drawing portion to which data lines provided to each column for actuating the pixels are drawn to be disposed substantially in parallel with each other, in which the drawing portion has an inspection terminal allocating layer in which predetermined data lines of a color other than a predetermined basic color are insulatively covered in a direction intersecting the drawing direction of the data lines, while data lines of the predetermined basic color that are not insulatively covered are exposed as an inspection signal input terminal.

In the arrangement, where the optical panel is displayed in color by using the two or more basic colors (for example, red, green and blue), the optical panel is checked for display unevenness or the like by lighting the optical panel by each basic color in the image display inspection of the optical panel.

Here, a common signal is concurrently input in the data lines for actuating the pixels of a common color. For example, the data lines connecting red pixels are concurrently input with a common signal.

As the inspection terminal allocating layer is provided, in which only the predetermined data lines of the predetermined basic color are exposed as a signal input terminal in the drawing portion of the data lines, continuity can be established with the data lines of the predetermined basic color only by pressing the wiring having a length in a direction orthogonal to the drawing direction of the data lines to the inspection terminal allocating layer.

When an inspection drive signal is input in the wiring in continuity with the data lines, the common signal is simultaneously sent to all the data lines of the predetermined basic color, thereby lighting the optical panel with the predetermined color. In this light-on state, the image display inspection of the optical panel is conducted for a defect such as display unevenness.

Like in related arts, if the probe terminals need to be connected with the data lines one by one for an image display inspection, the probe terminals become more minute as the pitch of the data lines becomes narrower. With the miniaturization of the data lines, processing cost of the inspection probe will increase, and the connection work between the data lines and the inspection probe will be complicated.

In contrast, according to aspect of the invention, the inspection terminal allocating layer is provided in the drawing portion of the optical panel and only predetermined data lines are exposed in the inspection terminal allocating layer, so that a connection can be established with the predetermined data lines only by pressing the common wiring to the inspection terminal allocating layer.

Thus, it is only necessary to press the wiring to the inspection terminal allocating layer, so that the connection work between the data lines and the inspection probe is extremely simple.

Since the optical panel is manufactured in large quantities, simplifying the connection work of the inspection probe to the optical panel can considerably shorten the total time required for the image display inspection, which presents an incredible effect that contributes to improvement of manufacturing efficiency.

The optical panel is not limited to the optical panel having the pixels that spontaneously emit a light, but may be an optical panel having pixels that emit a light by changing the transmissivity for adjusting illumination light of backlight.

The inspection terminal allocating layer may be preferably provided for each basic color in the drawing direction of the data lines.

In the arrangement, since the inspection terminal allocating layer is provided for each color, continuity with the data lines of each color can be established only by pressing the wiring of the inspection probe to the inspection terminal allocating layer of the data lines of each color.

And then, by inputting the inspection signal to the wiring portion connected with the data lines of each color, the liquid crystal display panel is lighted with each color to receive the image display inspection.

In the inspection terminal allocating layer, the data lines may be preferably exposed as the signal input terminal is layered with an electric conductor.

In the arrangement, when the wiring of the inspection probe is pressed to the inspection terminal allocating layer, the wiring contacts the electric conductor. Thereby, continuity between the data lines, which are signal input terminals, and the wiring is established via the electric conductor. When the data lines of a color other than the predetermined basic color are insulatively covered in the inspection terminal allocating layer, the top end of the data line of the predetermined basic color is shorter than that of the insulating film by the thickness of the insulating film. Hence, the wiring may not come into enough connection with the predetermined lines when being pressed to the inspection terminal allocating layer.

In contrast, according to aspect of the invention, since the data line being exposed as a signal input terminal is layered with the electric conductor, the height of the data line becomes larger by the thickness of the electric conductor, so that continuity between the wiring and the data line can be established more reliably via the electric conductor.

According to the aspect of the invention, the electric conductor preferably has a larger thickness than the insulating film. In the arrangement, the electric conductor further projects than the insulating film, so that the wiring of the inspection probe can reliably contact the electric conductor. Thus, the continuity between the data lines and the wiring of the inspection probe can be reliably established via the electric conductor.

An optical panel according to an aspect of the invention includes: scanning lines provided to each column for actuating pixels; and a drawing portion to which the scanning lines for actuating the pixels are drawn to be disposed substantially in parallel with each other, in which the drawing portion has an inspection terminal allocating layer in which predetermined ones out of the scanning lines are insulatively covered in a direction intersecting the drawing direction of the scanning lines, while other predetermined ones out of the scanning lines that are not insulatively covered are exposed as an inspection signal input terminal.

In the arrangement, where the optical panel has the scanning lines, the optical panel is inspected for a leakage between the scanning lines by inputting the inspection signal of opposite phases in the scanning lines next to each other.

For example, in inputting the inspection signals of opposite phases in the scanning lines next to each other, a certain common signal can be concurrently input in odd scanning lines and another common signal, which is in the opposite phase, can be input in even scanning lines.

As the inspection terminal allocating layer in which the predetermined scanning lines are exposed as a signal input terminal is provided in the drawing portion of the scanning lines, continuity with the predetermined scanning lines can be commonly established only by pressing the wiring having a length in a direction orthogonal to the drawing portion of the scanning lines to the inspection terminal allocating layer. When an inspection signal is input in the wiring connected with the predetermined scanning lines, the common signal is concurrently sent to the predetermined scanning lines, thereby lighting the optical panel on. In this light-on state, the image display inspection of the optical panel is conducted for a defect such as a leakage between the scanning lines.

Like in related arts, if probe terminals need to be connected with the scanning lines one by one for an image display inspection, the probe terminals become more minute as the pitch of the scanning lines becomes narrower. With the miniaturization of the scanning lines, processing cost of the inspection probe will increase, and the connection work between the scanning lines and the inspection probe will be complicated.

According to the aspect of the invention, the inspection terminal allocating layer is provided in the drawing portion of the optical panel, and only the predetermined scanning lines are exposed as a signal input terminal in the inspection terminal allocating layer, so that a connection with the predetermined scanning lines can be established only by pressing the common wiring to the inspection terminal allocating layer.

Thus, it is only necessary to press the wiring to the inspection terminal allocating layer, so that the connection work between the inspection probe and the scanning lines is extremely simple.

Since the optical panel is manufactured in large quantities, simplifying the connection work of the inspection probe to the optical panel can considerably shorten the total time required for the image display inspection, which presents an incredible effect that contributes to improvement of manufacturing efficiency.

In the electronics device according to the aspect of the invention, preferably, the inspection signal input terminal is a predetermined signal input terminal to which a common inspection signal can be input, and predetermined signal lines to which the common inspection signal can be input out of the signal lines that are insulatively covered in the inspection terminal allocating layer are drawn longer than the other signal lines and connected in a line-connecting portion.

In the optical panel according to the aspect of the invention, (in which the common data line for actuating the pixels is provided for each column), preferably, the data lines of at least one color other than the predetermined basic color are drawn longer than the other signal lines and connected in each line-connecting portion provided for each color.

The optical panel according to the aspect of the invention, (in which the scanning line for actuating the pixels is provided for each low), preferably, the inspection signal input terminal is a predetermined scanning line to which a common signal can be input, and the predetermined scanning lines to which the common inspection signal can be input out of the scanning lines that are insulatively covered in the inspection terminal allocating layer are drawn longer than the other scanning lines and connected in a line-connecting portion.

In those arrangements, in addition to the above described advantages as an electronics device and optical panel, continuity with the scanning lines connected in the line-connecting portion can be established only by connecting the wiring to the line-connecting portion, since the predetermined signal lines, the predetermined data lines or the predetermined scanning lines are collectively connected in the line-connecting portion.

Specifically, in order to connect the wiring for inputting the inspection drive signal to the scanning lines and the liquid crystal display panel, it is only necessary to press the wiring to the inspection terminal allocating layer. Especially, it is only necessary to connect only one wiring to the line-connecting portion, so that the connection work between the inspection probe and the scanning lines is extremely simple.

An inspection probe according to an aspect of the invention is temporarily connected with a signal line in inspecting characteristics of an electronics device and includes a board; and a wiring portion provided on the board, the wiring portion extending in a direction intersecting the drawing direction of the signal lines in correspondence with the inspection terminal allocating layer and contacting the inspection terminal allocating layer when being pressed on the signal lines from above so as to intersect the signal lines.

An inspection probe according to an aspect of the invention is temporarily connected with a data line in inspecting image display of an optical panel and includes a board; and a wiring portion provided on the board, the wiring portion extending in a direction intersecting the drawing direction of the data lines in correspondence with the inspection terminal allocating layer and contacting the inspection terminal allocating layer when being pressed on the data lines from above so as to intersect the data lines.

An inspection probe according to an aspect of the invention is temporarily connected with a scanning line in inspecting image display of an optical panel and includes a board; and a wiring portion provided on the board, the wiring portion extending in a direction intersecting the drawing direction of the scanning lines in correspondence with the inspection terminal allocating layer and contacting the inspection terminal allocating layer when being pressed on the scanning lines from above so as to intersect the scanning lines.

In those arrangements, the wiring portion and signal lines (data lines, scanning lines) can be in continuity with each other only by pressing the inspection probe to the drawing portion of the data lines or the scanning lines to press the wiring portion to the inspection terminal allocating layer, thereby the inspection probe can be attached to the optical panel. Accordingly, the connection work between the data lines or the scanning lines and the inspection probe is extremely simple, so that the efficiency of the image display inspection can be considerably improved.

On the other hand, the inspection probe only needs the wiring portion disposed on the board, thereby reducing the manufacturing cost of the inspection probe extremely low.

According to the aspect of the invention, the wiring portion may preferably have the communication wiring for transferring signals and the conductive resilient body covering the communication wiring.

In the arrangement, since the wiring portion has the conductive resilient body on the communication wiring, the conductive resilient body is elastically deformed to closely contact the data lines or scanning lines, when the wiring portion is pressed to the inspection terminal allocating layer. Thereby, the wiring portion and the signal lines (scanning lines, data lines) reliably come into connection via the resilient body to establish continuity.

In the inspection terminal allocating layer, when the signal lines other than the predetermined signal lines (data lines, scanning lines) are covered by the insulating film, the predetermined signal lines as a signal input terminal are shorter than the insulating film by the thickness of the insulating film. Still, the wiring portion can be elastically deformed to contact the predetermined signal lines (data lines, scanning lines) when being pressed to the inspection terminal allocating layer, so that continuity between the wiring portion and the signal lines (scanning lines, data lines) can be established.

The inspection probe of the aspect of the invention may preferably have, in addition to the board and the wiring portion, the contact portion disposed on the board, which contacts the line-connecting portion such that the wiring portion contacts the signal input terminal when being pressed on the signal lines (data lines, scanning lines) from above.

In the arrangement, the wiring portion and signal lines (data lines, scanning lines) can be in continuity with each other only by pressing the inspection probe to the drawing portion of the data lines or the scanning lines to press the wiring portion to the inspection terminal allocating layer, thereby the inspection probe can be attached to the optical panel. At the same time, the contact portion contacts the line-connecting portion, so that continuity is also established between the contact portion and the signal lines (data lines, scanning lines) connected in the line-connecting portion.

Accordingly, the connection work between the signal lines, the data lines or the scanning lines and the inspection probe is extremely simple, so that the efficiency of the image display inspection can be considerably improved.

Especially, the inspection probe only needs to be provided with the wiring to be pressed to the inspection terminal allocating layer and the contact portion to contact the line-connecting portion both on the board, so that the manufacturing cost of the inspection probe can be extremely reduced low.

An inspection device according to an aspect of the invention includes an inspection probe; and an inspection signal transmitter that inputs an inspection drive signal in an inspection signal input terminal (of the optical panel or the electronics device) via the inspection probe.

In the arrangement, the manufacturing cost of the inspection probe is extremely low, thereby allowing to produce the inspection device at low cost.

Further, the connection work between the inspection probe and the signal lines (data lines, scanning lines) of the optical panel or the electronics device is extremely simple, so that the efficiency of the image display inspection can be improved.

An inspection method of an optical panel according to an aspect of the invention includes connecting of an inspection probe with the data lines and the scanning lines of the optical panel; and signal-inputting of an inspection drive signal to the optical panel via the inspection probe.

In the arrangement, since the connection work to connect the inspection probe with the data lines or the scanning lines is extremely easy in the connecting step, the inspection efficiency of the inspection of the optical panel can be improved.

The inspection method of the optical panel according to the aspect of the invention may preferably includes cutting-off for cutting off a line-connecting portion in the signal-inputting after the inspection of the optical panel is finished.

In the arrangement, where the line-connecting portion is cut off in the cutting-off step because the signal lines (data lines, scanning lines) need to be all individual i.e. separate from each other after the inspection is finished, the signal lines to be contacted in the inspection terminal allocating layer are individual from the first. Hence, the number of the line-connecting portion to be cut off is small, for example, one or two. Thus, the number of time of cutting in the cutting-off step is small and the cutting step can be simple. As described above, since the connecting step and the cutting-off step can be simple, thereby improving the inspection efficiency of the optical panel.

### BRIEF DESCRIPTION OF THE DRAWINGS

The invention will be described with reference to the accompanying drawings, wherein like numbers reference like elements.

FIG. 1 shows an overall layout in which a liquid crystal display panel is connected in an inspection device according to a first exemplary embodiment of the invention;

FIG. 2 shows an overall arrangement of the liquid crystal display panel according to the first exemplary embodiment;

FIG. 3 is an enlarged view of a drawing portion of data lines according to the first exemplary embodiment;

FIG. 4 shows an arrangement of an inspection probe according to the first exemplary embodiment;

FIG. 5 is an enlarged view of a contacting portion where the inspection probe contacts the data lines in the drawing portion of the data lines according to the first exemplary embodiment;

FIG. 6 is a cross section showing a connection state where the inspection probe is connected with the data lines according to the first exemplary embodiment;

FIG. 7 is another cross section showing a connection state where a red wiring portion of an inspection probe is connected with a red-terminal allocating layer according to a second exemplary embodiment of the invention;

FIG. 8 shows an arrangement of a liquid crystal display panel according to a third exemplary embodiment;

FIG. 9 shows an arrangement of an inspection probe according to the third exemplary embodiment;

FIG. 10 is an enlarged view showing a drawing portion formed by data lines drawn from a liquid crystal display panel according to a forth exemplary embodiment;

FIG. 11 shows an arrangement of an inspection probe according to the forth exemplary embodiment;

FIG. 12 is another enlarged view of a contacting portion where the inspection probe contacts the data lines in the drawing portion of the data lines according to the forth exemplary embodiment;

FIG. 13 is a cross section showing a connection state where the inspection probe is connected with the data lines according to the forth exemplary embodiment;

FIG. 14 is another cross section showing a connection state where a red wiring portion of the inspection probe is connected with a red-terminal allocating layer according to a fifth exemplary embodiment of the invention;

FIG. 15 shows an arrangement of a liquid crystal display panel according to a sixth exemplary embodiment of the invention;

FIG. 16 shows an arrangement of an inspection probe according to the sixth exemplary embodiment;

FIG. 17 shows an arrangement of a display device according to a related art; and

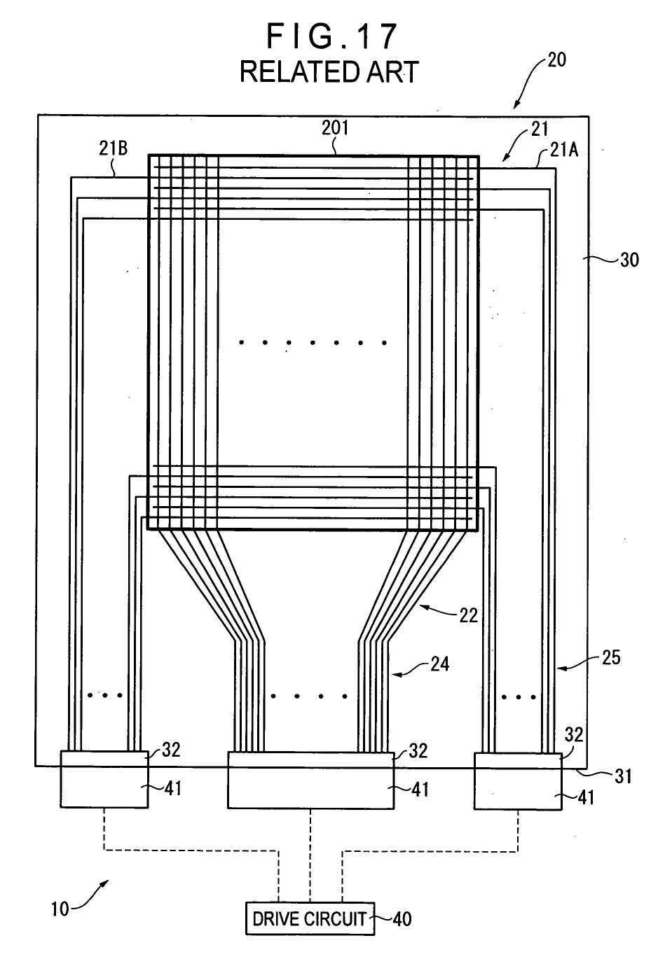

FIG. 18 is an enlarged view showing a connecting portion of an inspection probe and data lines according to the related art.

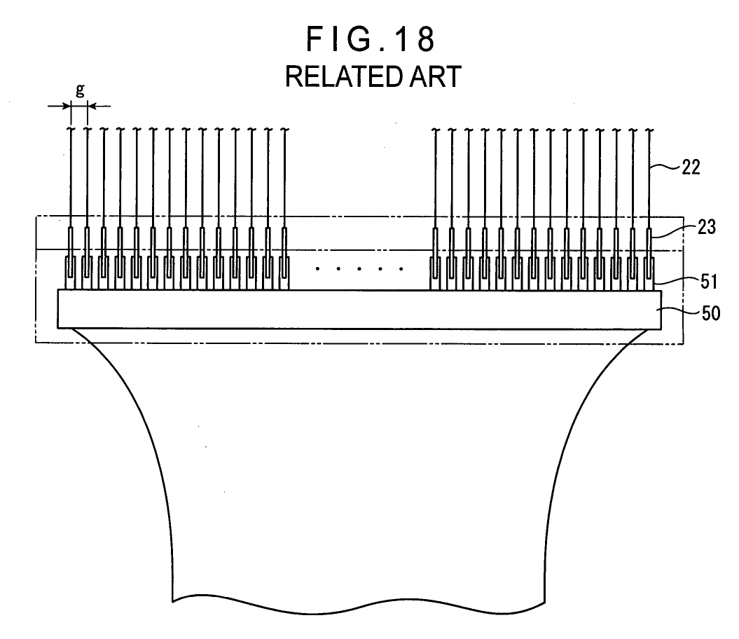

### DESCRIPTION OF EXEMPLARY EMBODIMENT(S)

Exemplary embodiments of the invention will be described below with reference to the attached drawings and the numerals assigned to respective elements shown in the drawings.

### 1 First Exemplary Embodiment

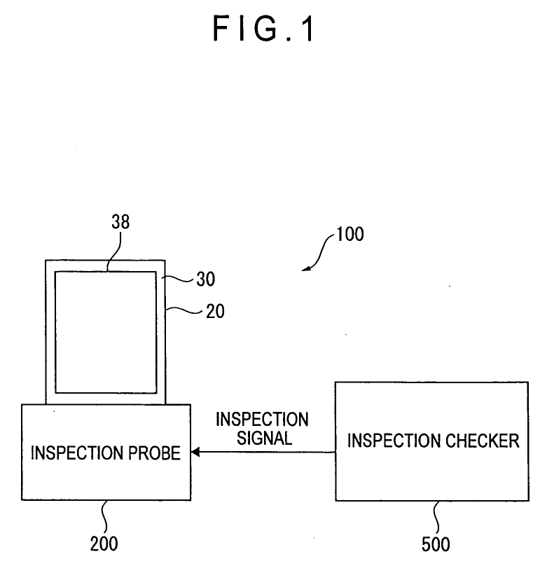

A first exemplary embodiment of an optical panel and an inspection device for inspecting the optical panel according to the invention will be described with reference to FIGS. 1 to 6.

FIG. 1 shows an overall layout in which a liquid crystal display panel 20 as the optical panel is connected in an inspection device 100.

An inspection probe 200 is connected at a side of a substrate 30 of the liquid crystal display panel 20. An inspection signal is input from an inspection checker (inspection signal transmitter) 500 via the inspection probe 200 to the liquid crystal display panel 20. An image display inspection of the liquid crystal display panel 20 is conducted by judging a light-on state of the thus lighted liquid crystal display panel 20.

First, the liquid crystal display panel 20 to be inspected and an outline of the inspection of the liquid crystal display panel 20 will be described.

In the image display inspection of the liquid crystal display panel 20, the inspection probe 200 is connected with data lines 22 and scanning lines 21 of the liquid crystal display panel 20 for the inspection. In the first exemplary embodiment, a case where the inspection probe 200 is connected with the data lines 22 of the liquid crystal display panel 20 is primarily explained.

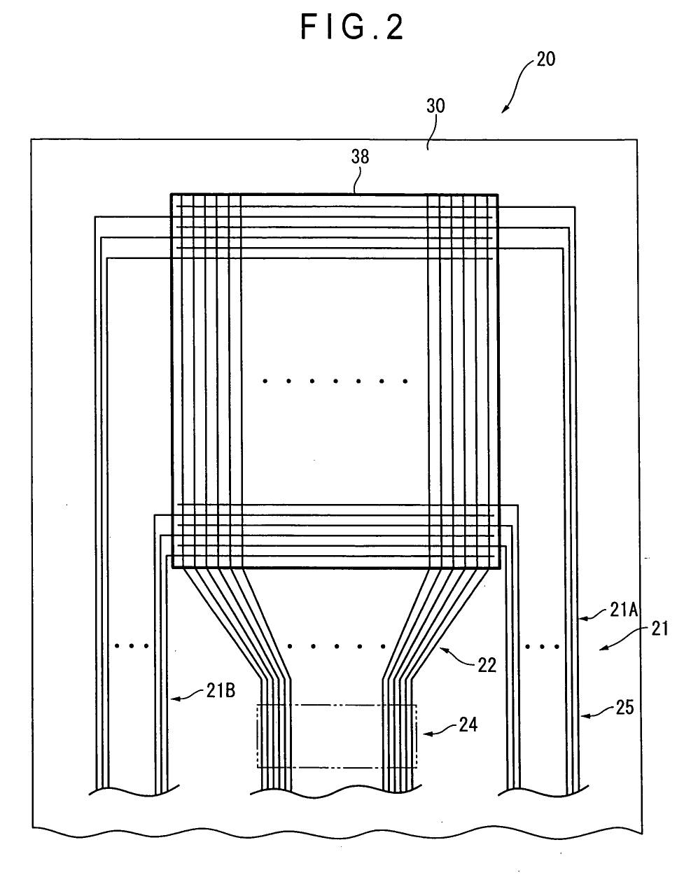

FIG. 2 shows an overall arrangement of the liquid crystal display panel 20.

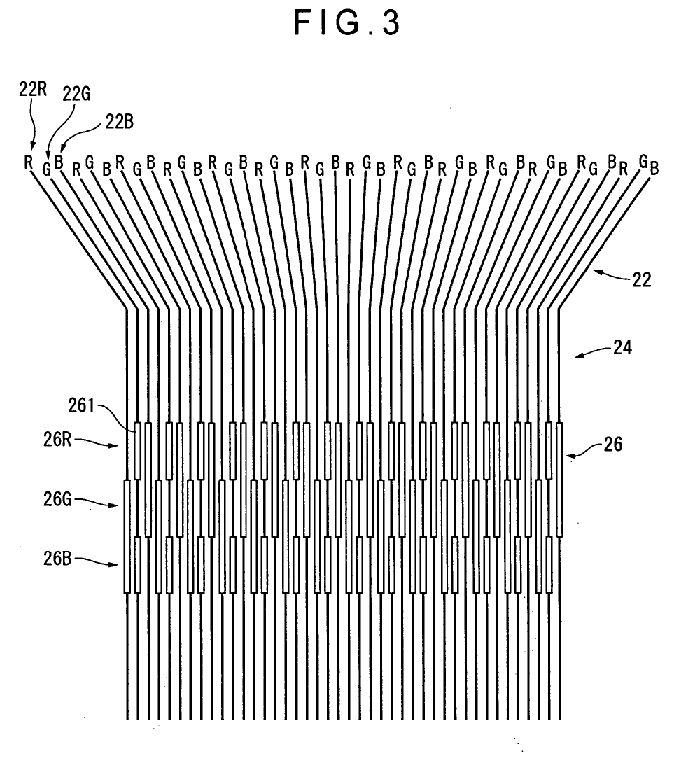

The liquid crystal display panel 20 to be inspected according to the invention is a liquid crystal display panel 20 that: displays an image in colors by using, e.g., R (red), G (green) and B (blue); and has pixels arrayed in rows and columns, the pixels in a common column emitting a common color of R (red), G (green) or B (blue) (see, for example, FIG. 3).

When seeing in rows, the colors of R (red), G (green) and B (blue) are repeatedly arrayed in this order.

Each pixel has liquid crystal cells (not shown) and thin-film two-terminal elements (switching element) (not shown) respectively provided to the liquid crystal cells. The data lines 22 are longitudinally wired (in columns) in the liquid crystal display panel 20, while the scanning lines 21 are laterally wired (in rows) in the liquid crystal display panel 20. In other words, the pixels in a common row are connected by a common scanning line 21, while the pixels in a common column, which are the pixels emitting a common color, are connected by a common data line 22.

Hereinafter, the data line 22 connecting the red pixels is called a red data line 22R, the data line 22 connecting the green pixels is called a green data line 22G, and the data line 22 connecting the blue pixels is called a blue data line 22B.

The data lines 22 and scanning lines 21 are drawn from a display 38 of the liquid crystal display panel 20 and collectively arranged to a lower side of a substrate 30 (the lower side in FIG. 2).

In detail, all the data lines 22 are directly drawn from the display 38 of the liquid crystal display panel 20 (e.g., the data lines are drawn downward in FIG. 2) and arranged in parallel to each other near the lower side of the substrate 30.

Aligning all the data lines 22 in parallel forms a drawing portion 24.

The scanning lines 21 are drawn in two opposite ways, depending on whether the scanning line is even or odd. Odd scanning lines 21A are drawn to the right, while even scanning lines 21B are to the left.

Both of the odd scanning lines 21A drawn to the right and the even scanning lines 21B drawn to the left are further extended to the lower side of the substrate 30 to be aligned in parallel to each other.

Aligning the scanning lines 21 in parallel forms the drawing portions 25.

In the image display inspection of the liquid crystal display panel 20, the pixels can be classified in three color groups of R (red), G (green) and B (blue), so that the liquid crystal display panel 20 is inspected for each color.

For example, in a light-on inspection for red, common signals are concurrently sent to all the data lines connecting the red pixels (red data lines 22R) to light the entire liquid crystal display panel with red.

In this state, the liquid crystal display panel 20 is checked for a point defect, a line defect or pixel unevenness in terms of red color, and then inspected for a defect such as a short between the data lines based on the found display defects.

If there is a defect such as a leakage between one red data line 22R and another data line (green data line 22G or blue data line 22B), the pixel cannot be properly lighted on, and thereby the defect can be detected.

Similarly, in a light-on inspection for green, common signals are concurrently sent to all the green data lines 22G to light the entire liquid crystal display panel with green, while in a light-on inspection for blue, common signals are concurrently sent to all the blue data lines 22B to light the entire liquid crystal display panel with blue.

FIG. 3 shows an enlarged view of the drawing portion 24 of the data lines 22.

As shown in FIG. 3, the drawing portion 24 has an inspection terminal allocating layer 26 in which the data lines 22 of a predetermined color are not provided with an insulating film 261 to be exposed as an inspection signal input terminal and the data lines 22 of another two colors are insulatively covered by the insulating film 261 in a direction orthogonal to the drawing direction of the data lines 22 The inspection terminal allocating layer 26 is provided for each color in the drawing direction of the data lines 22.

In FIG. 3, the inspection terminal allocating layers 26 i.e. a red-terminal allocating layer 26R, a green-terminal allocating layer 26G and a blue-terminal allocating layer 26B are arranged in this order from above.

In the red-terminal allocating layer 26R, only the red data lines 22R are exposed as a signal input terminal, while the green data lines 22G and blue data lines 22B are covered by the insulating film 261.

In the green-terminal allocating layer 26G, only the green data lines 22G are exposed as a signal input terminal, while the red data lines 22R and blue data lines 22B are covered by the insulating film 261.

And, in the blue-terminal allocating layer 26B, the blue data lines 22B are exposed as a signal input terminal, while the red data lines 22R and green data lines 22G are covered by the insulating film 261.

When the three inspection terminal allocating layers of the red-terminal allocating layer 26R, the green-terminal allocating layer 26G and the blue-terminal allocating layer 26B are provided, the layer may have any width. For example, the width, which is orthogonal to the length of the inspection terminal allocating layer, can be determined such that the insulating film 261 can be easily formed.

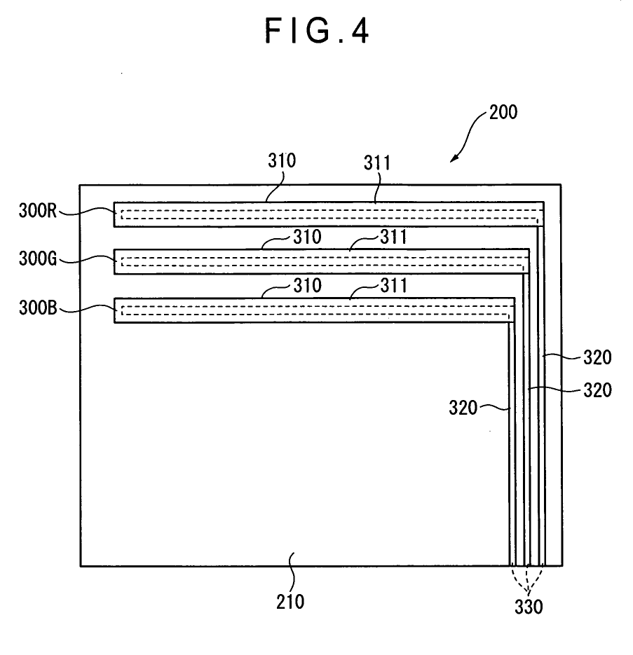

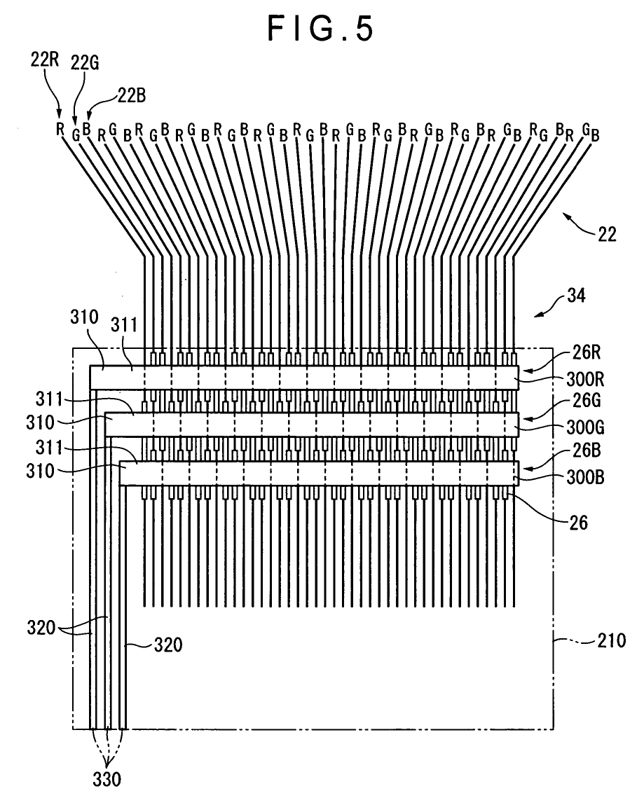

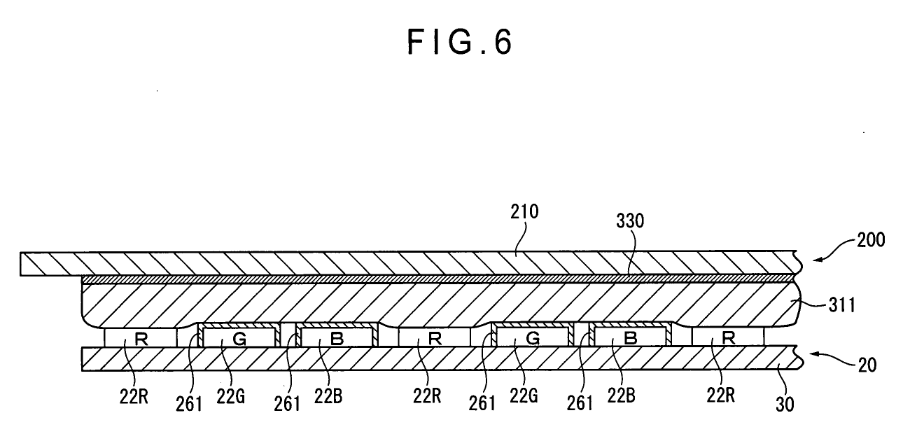

Next, the inspection probe 200 will be described with reference to the FIGS. 4 to 6. FIG. 4 shows an arrangement of the inspection probe. FIG. 5 is an enlarged view of a contacting portion where the inspection probe contacts the data lines in the drawing portion. FIG. 6 is a cross section showing a connection state where the inspection probe is connected with the data lines.

The inspection probe 200 has a board 210 and three wiring portions 300R, 300G and 300B that are arranged on the board 210.

When the inspection probe 200 is pressed to the drawing portion 24 of the data lines 22, the wiring portion 300R, 300G or 300B comes into contact with the inspection terminal allocating layer 26R, 26G or 26B, that is, comes into connection with the data lines 22 as a signal input terminal, which are exposed in the inspection terminal allocating layer 26R, 26G or 26B.

The three wiring portions are provided: a red wiring portion 300R to contact with the red-terminal allocating layer 26R; a green wiring portion 300G to contact with the green-terminal allocating layer 26G; and a blue wiring portion 300B to contact with the blue-terminal allocating layer 26B.

In FIG. 4, the red wiring portion 300R, the green wiring portion 300G and the blue wiring portion 300B are arranged in this order from above.

As shown in FIG. 4, each wiring portion 300R, 300G or 300B has a main shaft section 310 and a coupling shaft section 320 and is arranged in a shape where the main shaft section 310 is laterally and linearly extended at an upper portion of the board 210 and the coupling shaft section 320 is drawn downward from one end of the main shaft section 310 and input with an inspection signal from the inspection checker 500 at an lower end. The wiring portion 300R, 300G or 300B further has a conductive communication wiring 330 disposed on the board 210; a bump 311 disposed on the communication wiring 330 in the main shaft section 310 of the wiring portion 300R, 300G, 300B (see FIG. 6).

The communication wiring 330 is wired along the main shaft section 310 and the coupling shaft section 320.

The bump 311 is a conductive resilient body that is layered on the communication wiring 330 in the main shaft section 310. The bump 311 is formed in a convex shape on the board 210 having a predetermined height.

Next, the image display inspection of the liquid crystal display panel 20 using the inspection device 100 will be described.

In the image display inspection of the liquid crystal display panel 20, firstly, the inspection probe 200 is attached and connected to the drawing portion 24 of the data lines 22 (connecting step).

In the attachment, the inspection probe 200 is pressed to the drawing portion 24 of the data lines 22 such that the main shaft sections 310 of the wiring portions 300R, 300G and 300B are orthogonal to the data lines 22, thereby the main shaft sections 310 of the wiring portions 300R, 300G and 300B are respectively placed on the corresponding inspection terminal allocating layers 26R, 26G and 26B into a contacting state.

The bumps 311 of the wiring portions 300R, 300G and 300B thus come into contact with the data lines 22 being exposed in the inspection terminal allocating layers 26R, 26G and 26B to make a connection between the wiring portions 300R, 300G, 300B and the corresponding data lines 22R, 22G, 22B.

As shown in FIG. 5, when the main shaft section 310 of the wiring portion 300R, 300G or 300B is pressed to the inspection terminal allocating layer 26R, 26G or 26B, the bump 311 is not connected with the data lines 22 insulated by the insulating film 261 but contacts the exposed data lines 22 to make a connection.

For example, in a case of the red-terminal allocating layer 26R, the red data lines 22R are exposed as a signal input terminal and the green data lines 22G and blue data lines 22B are covered by the insulating film 261. Hence, when the bump 311 of the red wiring portion 300R is pressed to the red-terminal allocating layer 26R, the bump 311 only contacts the red data lines 22R to make a connection therebetween.

As the cross section in FIG. 6 shows, since the green data lines 22G and the blue data lines 22B are covered by the insulating film 261, the red data lines 22R has a shorter height than that of the green data lines 22G and the blue data lines 22B by a thickness of the insulating film 261. However, the bump 311 is elastically deformed when being pressed to the red-terminal allocating layer 26R, so that the bump 311 can reach the red data lines 22 to be connected.

In the same way, the bump 311 of the green wiring portion 300G is connected with the green data lines 22G when being pressed to the green-terminal allocating layer 26G, while the bump 311 of the blue wiring portion 300B is connected with the blue data lines 22B when being pressed to the blue-terminal allocating layer 26B.

In this state, inspection drive signals are input to the wiring portions 300R, 300G and 300B in turn from the inspection checker 500.

For example, when conducting a light-on inspection for red pixels, the inspection signals are input to the red wiring portion 300R from the inspection checker.

Then, the inspection signals are input simultaneously to all the red data lines 22R from the communication wiring 330 of the red wiring portion 300R via the bump 311.

At this time, the inspection signals are not input to the green data lines 22G or the blue data lines 22B.

Therefore, the voltage is applied to the red pixels via the red data lines 22R, lighting all the red pixels on. The image display inspection for red is conducted by inspection personnel by checking the light-on state with eyes or based on an image picked by the CCD camera. Subsequently, the light-on inspections for green and blue are conducted in turn in the similar way.

When the image display inspection has been finished, the inspection probe 200 is removed from the data lines 22. Good liquid crystal display panels 20 are sent for a next manufacturing step.

The following advantages can be obtained according to the first exemplary embodiment that has the above-stated arrangement.

(1) Since the inspection terminal allocating layers 26R, 26G, 26B are provided to the drawing portion 24 of the data lines 22 and only predetermined data lines 22 are exposed as a signal input terminal in each inspection terminal allocating layer 26R, 26G, 26B, a connection with the predetermined data lines 22 can be established only by pressing the wiring portion 300R, 300G or 300B of the inspection probe 200 to the inspection terminal allocating layer 26R, 26G or 26B. In addition, since the data lines 22 and the inspection probe 200 can be connected only by pressing the wiring portions 300R, 300G, 300B of the inspection probe 200 to the inspection terminal allocating layers 26R, 26G, 26B, the connection work between the data lines 22 and the inspection probe 200 is extremely simple. Considering that the liquid crystal display panel 20 is manufactured in large quantities, simplifying the connection work of the inspection probe 200 for each liquid crystal display panel 20 can significantly shorten the total time required for the image display inspection, which is an incredible effect that contributes to improvement of manufacturing efficiency.

(2) Since the inspection terminal allocating layers 26R, 26G, 26B are provided for the respective colors, continuity with the data lines 22 of each color can be established only by pressing the wiring portion 300R, 300G or 300B of the inspection probe 200 to the inspection terminal allocating layer 26R, 26G or 26B of the data lines 22 of each color. And then, by inputting the inspection signal in the wiring portion 300R, 300G or 300B connected with the data lines 22 of each color, the liquid crystal display panel 20 is lighted with each color to receive the image display inspection.

(3) Since the wiring portion 300R, 300G, 300B is provided with the bump 311 on the communication wiring 330, when the wiring portion 300R, 300G or 300B is pressed to the inspection terminal allocating layer 26R, 26G or 26B, the bump 311 is elastically deformed to closely contact the data lines 22R, 22G or 22B. Thus, the wiring portions 300R, 300G, 300B can be reliably connected with the data lines 22R, 22G, 22B via the bumps 311 into continuity.

Consequently, it is possible to prevent an inspection error caused by a contact failure between the inspection probe 200 and the data lines 22R, 22G 22B, so that the image display inspection can be appropriately conducted.

In the inspection terminal allocating layer 26, predetermined data lines 22 (signal input terminal) have a height shorter than that of the other data lines by the thickness of the insulating film 261, because the other data lines are covered by the insulating film 261. However, when the wiring portion 300R, 300G, 300B is pressed to the inspection terminal allocating layer 26R, 26G, 26B, the bump 311 can be elastically deformed to contact the predetermined data lines 22, which have a top end lower than that of the insulating film 261, to establish continuity between the wiring portion 300R, 300G or 300B and the data lines 22R, 22G or 22B.

(4) Since the liquid crystal display panel 20 has the inspection terminal allocating layers 26R, 26G, 26B, the inspection probe 200 only needs to be provided with the wiring portions 300R 300G, 300B on the substrate 30, which are to be pressed to the inspection terminal allocating layers 26R, 26G, 26B. Thus, the inspection probe 200 can have such a simple structure, so that the manufacturing cost of the inspection probe 200 can be considerably reduced.

(5) When connecting the inspection probe 200 with the data lines 22 of the liquid crystal display panel 20 for conducting the image display inspection of the liquid crystal display panel 20, pressing the wiring portions 300R, 300G, 300B of the inspection probe 200 to the inspection terminal allocating layers 26R, 26G, 26B is only required, so that the connection work between the inspection probe 200 and the data lines 22 can be extremely simple. Consequently, the work time for connecting the inspection probe 200 to the liquid crystal display panel 20 can be significantly shortened, thereby improving the inspection efficiency of the liquid crystal display panel 20.

### 2 Second Exemplary Embodiment

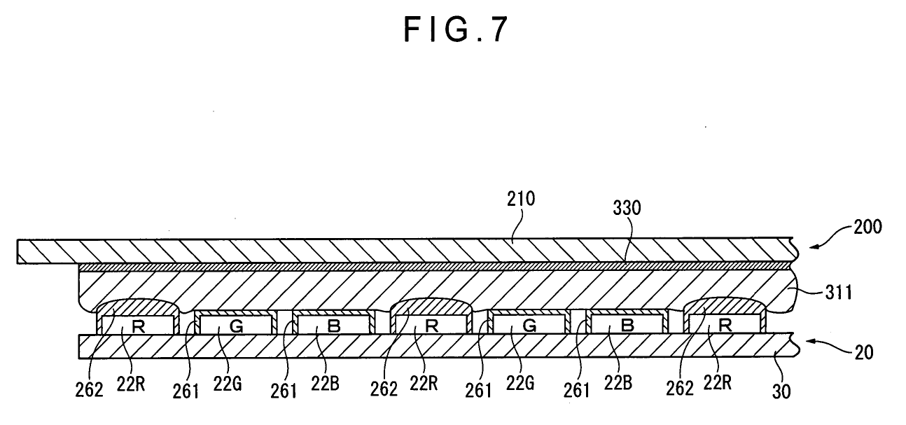

Next, a second exemplary embodiment of the optical panel according to the invention will be described with reference to the FIG. 7.

Although basic arrangements of the liquid crystal display panel of the second exemplary embodiment are similar to those of the liquid crystal display panel of the first exemplary embodiment, the second exemplary embodiment has a feature that an electric conductor is layered on the data lines being exposed as a signal input terminal in the inspection terminal allocating layer.

FIG. 7 is a cross section showing a connection state where the red wiring portion 300R of the inspection probe 200 is connected with the red-terminal allocating layer 26R in the drawing portion 24 of the data lines 22.

Regarding the red-terminal allocating layer 26R, the green data lines 22G and the blue data lines 22B, except for the red data lines 22R, are covered by the insulating film 261.

On the other hand, the red data lines 22R are layered with an electric conductor 262 that is formed of a conductive resilient body.

The electric conductor 262 has a larger thickness than the insulating film 261, so that the electric conductor 262 is projecting than the insulating film 261.

As shown in FIG. 7, in the above arrangement, when the bump 311 of the inspection probe 200 is pressed to the red-terminal allocating layer 26R, the bump 311 contacts the electric conductor 262 layered on the red data line 22R. When the bump 311 is more strongly pressed, both of the bump 311 and the electric conductor 262 are elastically deformed to more closely contact to each other. Thereby, continuity between the red data line 22R and the communication wiring 330 can be reliably established via the bump 311 and the electric conductor 262.

According to the arrangement, since the data line 22 being exposed as a signal input terminal is layered with the electric conductor 262, the height of the data line 22 becomes larger by the thickness of the electric conductor 262, so that continuity between the bump 311 and the data line 22 is established via the electric conductor 262. Due to the thickness of the electric conductor 262, the electric conductor 262 projects higher than the insulating film 261, so that the bump 311 of the inspection probe 200 and the electric conductor 262 can reliably contact to each other. Thus, the continuity between the data lines 22 and the communication wiring 330 of the inspection probe 200 can be reliably established via the bumps 311 and the electric conductors 262.

Further, since the electric conductor 262 is also elastic, both of the bump 311 and the electric conductor 262 can be elastically deformed, thereby widening the contact area when being pressed to each other. Therefore, the bump 311 and the electric conductor 262 can be more reliably connected to each other.

### 3 Third Exemplary Embodiment

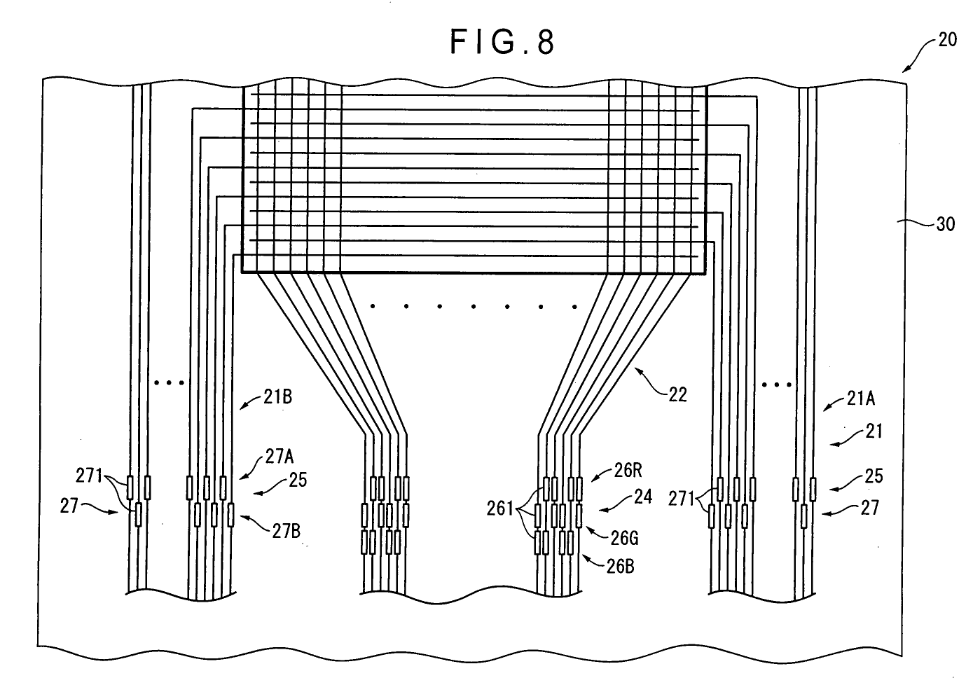

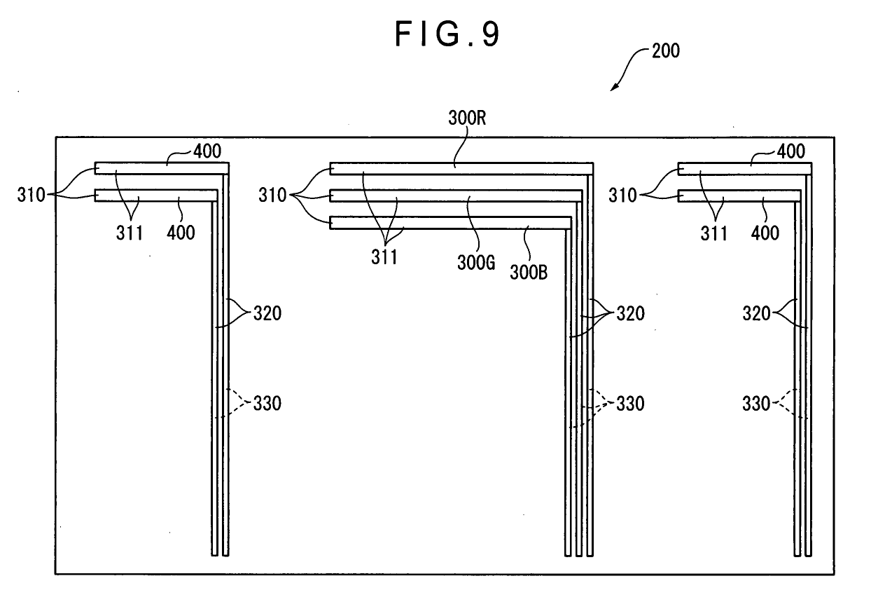

A third exemplary embodiment of the invention will be described with reference to the FIGS. 8 and 9.

Although basic arrangements of the third exemplary embodiment are similar to those of the first exemplary embodiment, the third exemplary embodiment has features that the inspection terminal allocating layer is also provided for the drawing portion 25 of the scanning lines 21 and that the inspection probe 200 is provided with the wiring portions 300R, 300G, 300B that are connected with the inspection terminal allocating layers 26R, 26G, 26B of the scanning lines 21.

FIG. 8 shows an arrangement of the liquid crystal display panel of the third exemplary embodiment. FIG. 9 shows an arrangement of the inspection probe of the third exemplary embodiment.

In FIG. 8, the drawing portion 24 of the data lines 22 is provided with the inspection terminal allocating layers 26R, 26G, 26B.

The drawing portions 25 of the scanning lines 21 also have an inspection terminal allocating layer 27.

Regarding the scanning lines 21, the odd scanning lines 21A are drawn to the right, while the even scanning lines 21B are drawn to the left. In both of the drawing portions 25 on the right and left, the inspection terminal allocating layer 27 is provided in a direction orthogonal to the drawing direction of the scanning lines 21. In the inspection terminal allocating layer 27, the insulating film 271 is provided to the scanning lines 21 having a predetermined pitch, but predetermined scanning lines 21 are exposed as a signal input terminal.

Specifically, in the inspection terminal allocating layers 27 of the scanning lines 21 on the right and left, the insulating film 271 is provided to every two scanning lines, so that remaining every two scanning lines 21 are exposed as a signal input terminal. The inspection terminal allocating layer 27 of the scanning lines 21 has an upper inspection terminal allocating layer 27A and a lower inspection terminal allocating layer 27B. The scanning lines 21 insulatively covered in the upper inspection terminal allocating layer 27A are exposed in the lower inspection terminal allocating layer 27B.

FIG. 9 shows an arrangement of the inspection probe 200 of the inspection device of the third exemplary embodiment. The basic arrangements of the inspection probe 200 of the third exemplary embodiment are similar to those of the first exemplary embodiment. However, in the third exemplary embodiment, the wiring portions 300R, 300G, 300B, which are connected with the data lines 22, are provided in a middle portion of the board 210, and two wiring portions 400 for scanning lines, which are connected with the scanning lines 21, are provided on each of the right and the left of the wiring portions 300R, 300G, 300B.

The arrangement of the wiring portion for scanning lines 400 is similar to that of the wiring portion 300R, 300G, 300B as described in the first exemplary embodiment. Specifically, the wiring portion 300R, 300G, 300B is constituted of the main shaft section 310 and the coupling shaft section 320 and is provided with the communication wiring 330 and the bump 311.

In the arrangement, when connecting the inspection probe 200 to the liquid crystal display panel 20, the wiring portions 300R, 300G, 300B, 400 of the inspection probe 200 are pressed to the corresponding inspection terminal allocating layers 26R, 26G, 26B, 27A, 27B. Thereby, the inspection probe 200 can be simultaneously connected with both of the data lines 22 and the scanning lines 21.

### 4 Forth Exemplary Embodiment

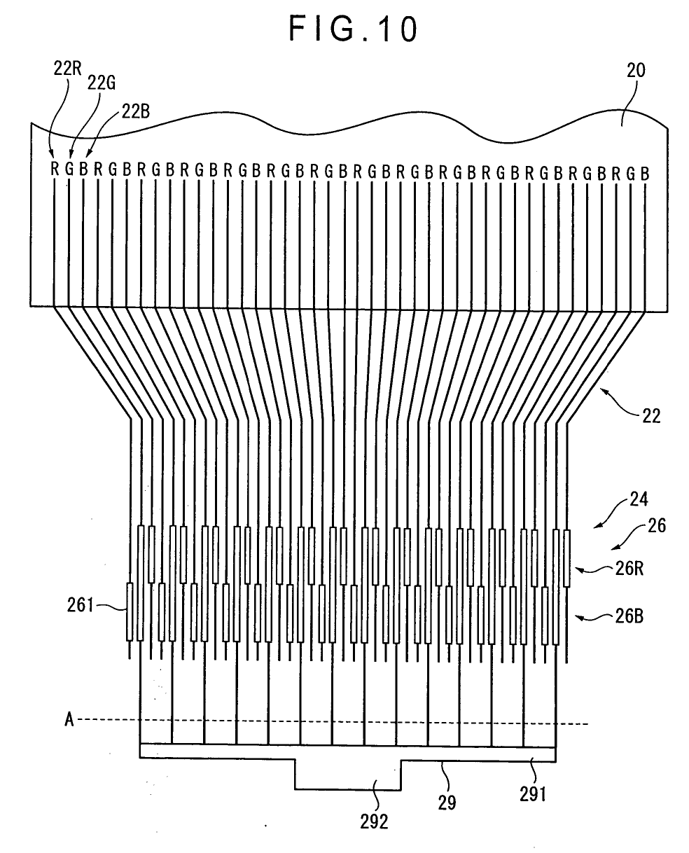

A forth exemplary embodiment of the invention will be described with reference to the FIGS. 10 to 13.

The present exemplary embodiment relates to an inspection of the liquid crystal display panel as an optical panel using the inspection device and has basic arrangements similar to those of the first exemplary embodiment described above. Hence, the liquid crystal display panel 20, the substrate 30, the inspection probe 200, the inspection checker (inspection signal transmitter) 500 or the like will not be repeatedly explained.

In FIG. 10, similarly to the first exemplary embodiment, the drawing portion 24 of the data lines 22 of the present exemplary embodiment is provided with the inspection terminal allocating layer 26.

In the present exemplary embodiment, the inspection terminal allocating layer 26 has the red-terminal allocating layer 26R and the blue-terminal allocating layer 26B, which are arranged in this order from above, but does not have the green-terminal allocating layer 26G. Alternatively, the common line-connecting portion 29 is provided. In detail, the green data lines 22G are extended further downward relative to the red-terminal allocating layer 26R and the blue-terminal allocating layer 26B to be connected to the common line connecting portion 29.

The line-connecting portion 29 has a common line 291 to which all lower ends of the green data lines 22G are commonly connected and a terminal portion 292 that juts out by a predetermined distance substantially in the middle of the common line 291.

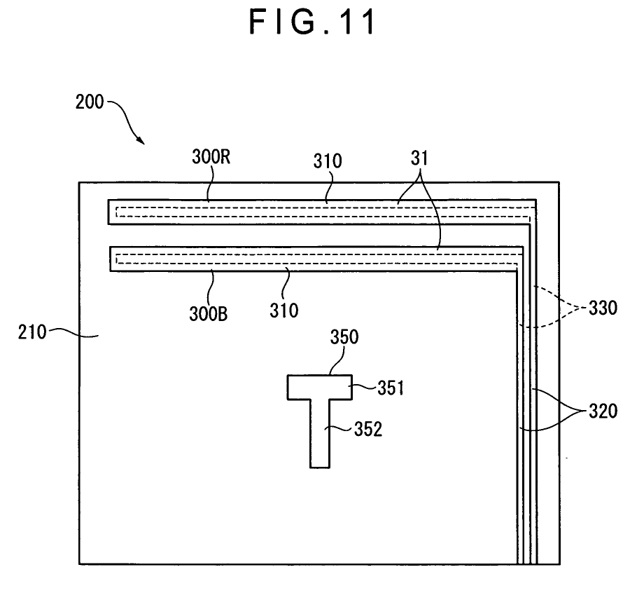

In FIG. 11, the inspection probe 200 has the board 210; the two wiring portions 300R and 300B connected with the inspection terminal allocating layer 26; and a contact portion 350 connected with the line-connecting portion 29.

The wiring portions 300R, 300B contact the inspection terminal allocating layers 26R and 26B to be connected with the data lines 22 as a signal input terminal. The structure of the wiring portion 300R, 300B is similar to that of the first exemplary embodiment, so that no same description will be repeated. Since the present exemplary embodiment employs the line-connecting portion 29 and the contact portion 350 for green system, the wiring portion 300G of the first exemplary embodiment is not provided.

The contact portion 350 is a conductive pad positioned substantially at the center of the board 210 so as to contact the line-connecting portion 29 when the inspection probe 200 is pressed to the drawing portion 24 of the data lines 22 such that the wiring portions 300R, 300B contact the inspection terminal allocating layers 26R, 26B. The contact portion 350 has a contact head 351 that contacts the terminal portion 292 of the line-connecting portion 29 to make a connection therebetween and a signal input pad 352 that extends downward from the contact head 351 and in which an inspection signal from the inspection checker 500 is input.

Next, the image display inspection of the liquid crystal display panel 20 using the inspection device 100 will be described.

In the image display inspection of the liquid crystal display panel 20, the inspection probe 200 is attached to the drawing portion 24 of the data lines 22, thereby the inspection probe 200 being connected with the data lines 22 (connecting step).

In the attachment, the inspection probe 200 is pressed to the drawing portion 24 of the data lines 22 such that the main shaft sections 310 of the wiring portion 300R, 300B is orthogonal to the data lines 22, thereby the main shaft sections 310 of the wiring portions 300R, 300B are respectively placed on the corresponding inspection terminal allocating layers 26R, 26B into a contacting state.

The bump 311 of the wiring portion 300R, 300B thus comes into contact with the data lines 22 being exposed in the inspection terminal allocating layers 26R, 26B to make a connection between the wiring portion 300R, 300B and the corresponding data lines 22R, 22B. At this time, the contact head 351 of the contact portion 350 also contacts the terminal portion 292 of the line-connecting portion 29 to establish continuity between the green data lines 22G, which are connected in the line-connecting portion 29, and the contact portion 350.

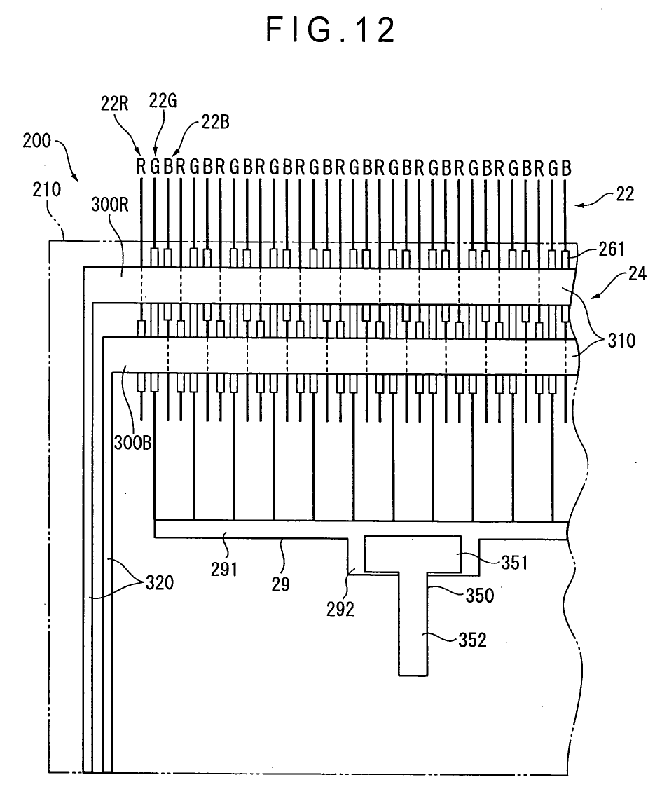

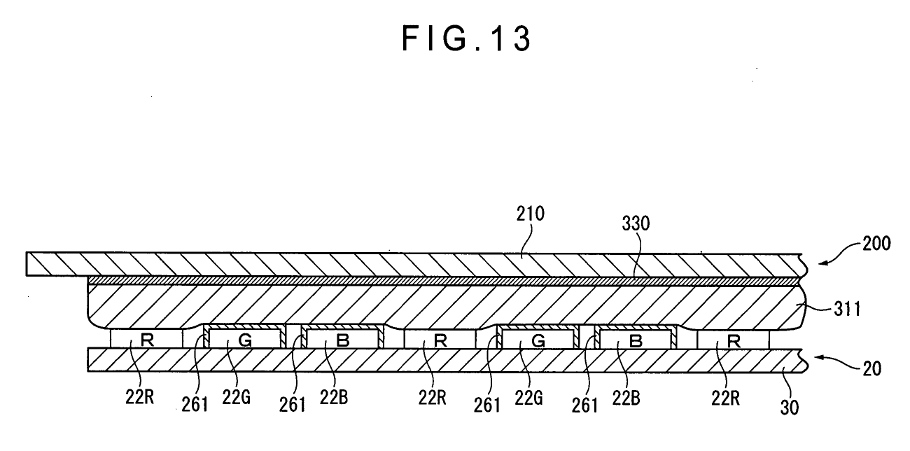

FIG. 12 is an enlarged view of a contacting portion where the inspection probe 200 contacts the data lines 22 in the drawing portion 24 of the data lines 22. And, FIG. 13 is a cross section showing a connection state where the inspection probe 200 is connected with the data lines 22.

As shown in FIG. 12, when the main shaft section 310 of the wiring portion 300R, 300B is pressed to the inspection terminal allocating layer 26R, 26B, the bump 311 is not connected with the data lines 22 insulated by the insulating film 261 but contacts the exposed data lines 22R, 22B to make a connection.

For example, in a case of the red-terminal allocating layer 26R, the red data lines 22R are exposed as a signal input terminal and the green data lines 22G and blue data lines 22B are covered by the insulating film 261. Hence, when the bump 311 of the red wiring portion 300R is pressed to the red-terminal allocating layer 26R, the bump 311 only contacts the red data lines 22R to make a connection therebetween.

As the cross section in FIG. 13 shows, since the green data lines 22G and the blue data lines 22B are covered by the insulating film 261, the red data lines 22R has a shorter height than that of the green data lines 22G and the blue data lines 22B by a thickness of the insulating film 261. However, the bump 311 is elastically deformed when being pressed to the red-terminal allocating layer 26R, so that the bump 311 can reach the red data lines 22 to be connected.

Similarly, the bump of the blue wiring portion 300B are connected with the blue data lines 22B when being pressed to the blue-terminal allocating layer 26B.

Since the green data lines 22G are connected in the line-connecting portion 29, the connection between the contact head 351 of the contact portion 350 and the terminal portion 292 of the line-connecting portion 29 establishes continuity between the contact portion 350 and the green data lines 22G.

In this state, inspection drive signals are input to the wiring portions 300R, 300B and the contact portion 350 from the inspection checker 500.

For example, when conducting a light-on inspection for red pixels, the inspection signals are input to the red wiring portion 300R from the inspection checker.

Then, the inspection signals are input simultaneously to all the red data lines 22R from the communication wiring 330 of the red wiring portion 300R via the bump 311.

At this time, the inspection signals are not input to the green data lines 22G or the blue data lines 22B.

Therefore, the voltage is applied to the red pixels via the red data lines 22R, lighting all the red pixels on. The image display inspection for red is conducted by inspection personnel by checking the light-on state with eyes or based on an image picked by the CCD camera. Subsequently, in an inspection for blue, the inspection signal is input to the blue wiring portion 300B in a similar manner, thereby conducting a light-on inspection for blue. In the light-on inspection for green, the inspection signal is input from the inspection checker 500 to the contact portion 350. Then, the inspection signal is input via the contact portion 350 to the green data lines 22G to light green pixels of the inspection probe 200 on. The image display inspection for green is conducted based on the light-on state.

When the image display inspection has been finished, the inspection probe 200 is removed from the data lines 22. Good liquid crystal display panels 20 are sent for a next manufacturing step.

Herein, all the data lines 22 need to be individual i.e. separated from each other for incorporating the liquid crystal display panel 20 in an actual product, and the line-connecting portion 29 is cut off with laser at a line A indicated by the reference A in FIG. 10 (cutting-off step).

The following advantages can be obtained according to the forth exemplary embodiment that has the above-stated arrangement.

(6) Since the inspection terminal allocating layers 26R, 26B are provided to the drawing portion 24 of the data lines 22 and only predetermined data lines 22 (red data lines 22R, blue data lines 22B) are exposed as a signal input terminal in each inspection terminal allocating layer 26R, 26B, a connection with the predetermined data lines 22 (red data lines 22R, blue data lines 22B) can be established only by pressing the wiring portion 300 of the inspection probe 200 to the inspection terminal allocating layer 26R, 26B.

Regarding the green data lines 22G connected in the line-connecting portion 29, continuity can be established commonly with all the green data lines 22G only by wiring the green data lines 22G with the line-connecting portion 29.

As described above, the inspection probe 200 can be connected with the liquid crystal display panel 20 only by pressing the wiring portions 300R, 300B to the inspection terminal allocating layers 26R, 26B and by connecting the contact portion 350 to the line-connecting portion 29, so that the connection work for connecting the inspection probe 200 with the data lines 22 is extremely simple.

(7) Since the liquid crystal display panel 20 has the inspection terminal allocating layers 26R, 26B and the line-connecting portion 29, it is only necessary to provide the inspection probe 200 with the wiring portions 300R, 300B to be pressed to the inspection terminal allocating layers 26R, 26B as well as the contact portion 350 to be in contact with the line-connecting portion 29, the wiring portions 300R, 300B and the contact portion 350 being provided on the board 210. Thus, the inspection probe 200 can have such a simple structure, so that the manufacturing cost of the inspection probe 200 can be considerably reduced.

(8) Since the wiring portion 300 is provided with the bump 311 on the communication wiring 330, when the wiring portion 300R or 300B is pressed to the inspection terminal allocating layer 26R or 26B, the bump 311 is elastically deformed to closely contact the data lines 22R or 22B. Thus, the wiring portions 300R, 300B can be reliably connected with the data lines 22R, 22B via the bumps 311 into continuity. In the inspection terminal allocating layer 26R, 26B, predetermined data lines 22 (signal input terminal) have a height shorter than that of the other data lines by the thickness of the insulating film 261, because the other data lines are covered by the insulating film 261. However, when the wiring portion 300R, 300B is pressed to the inspection terminal allocating layer 26R, 26B, the bump 311 can be elastically deformed to contact the predetermined data lines 22, which have a top end lower than that of the insulating film 261, to establish continuity between the wiring portion 300R, 300B and the data lines 22R, 22B.

(9) After the inspection is finished, the line-connecting portion 29 is to be cut off, because the data lines 22 need to be individual i.e. separated from each other. However, the data lines 22 that are connected with the inspection probe 200 in the inspection terminal allocating layers 26R, 26B are individual from the first, so that only one cutting process of the line-connecting portion 29 is necessary. Thus, the number of time of cutting process with laser is small and the cutting step can be simple.

### 5 Fifth Exemplary Embodiment

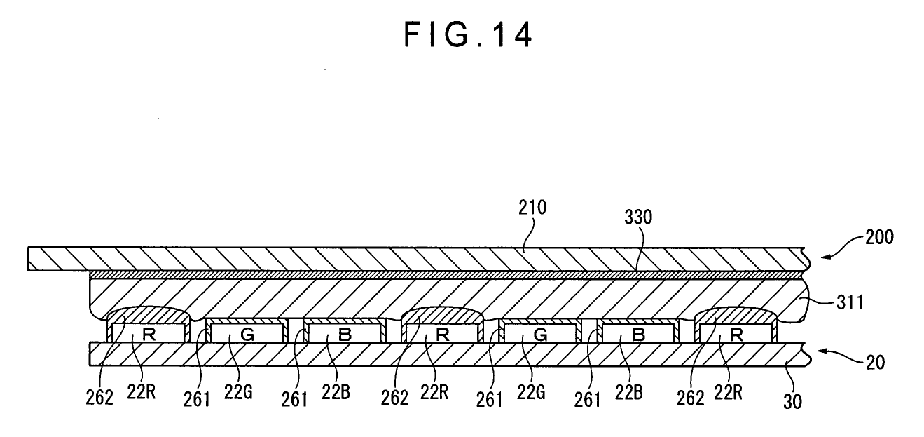

Next, a fifth exemplary embodiment of the optical panel according to the invention will be described with reference to the FIG. 14.

Although basic arrangements of the liquid crystal display panel of the fifth exemplary embodiment are similar to those of the liquid crystal display panel of the fourth exemplary embodiment, the fifth exemplary embodiment has a feature that an electric conductor is layered on the data lines being exposed as a signal input terminal in the inspection terminal allocating layer.

FIG. 14 is a cross section showing a connection state where the red wiring portion 300R of the inspection probe 200 is connected with the red-terminal allocating layer 26R in the drawing portion 24 of the data lines 22.

Regarding the red-terminal allocating layer 26R, the green data lines 22G and the blue data lines 22B, except for the red data lines 22R, are covered by the insulating film 261. On the other hand, the red data lines 22R are layered with the electric conductor 262 that is formed of a conductive resilient body. The electric conductor 262 has a larger thickness than the insulating film 261, so that the electric conductor 262 is projecting than the insulating film 261.

As shown in FIG. 14, in the above arrangement, when the bump 311 of the inspection probe 200 is pressed to the red-terminal allocating layer 26R, the bump 311 contacts the electric conductor 262 layered on the red data line 22R. When the bump 311 is more strongly pressed, both of the bump 311 and the electric conductor 262 are elastically deformed to more closely contact to each other. Thereby, continuity between the red data line 22R and the communication wiring 330 can be reliably established via the bump 311 and the electric conductor 262.

According to the arrangement, since the data line 22 being exposed as a signal input terminal is layered with the electric conductor 262, the height of the data line 22 becomes larger by the thickness of the electric conductor 262, so that continuity between the bump 311 and the data line 22 is established via the electric conductor 262. Due to the thickness of the electric conductor 262, the electric conductor 262 projects higher than the insulating film 261, so that the bump 311 of the inspection probe 200 and the electric conductor 262 can reliably contact to each other. Thus, the continuity between the data lines 22 and the communication wiring 330 of the inspection probe 200 can be reliably established via the bumps 311 and the electric conductors 262.

Further, since the electric conductor 262 is also elastic, both of the bump 311 and the electric conductor 262 can be elastically deformed, thereby widening the contact area when being pressed to each other. Therefore, the bump 311 and the electric conductor 262 can be more reliably connected to each other.

### 6 Sixth Exemplary Embodiment

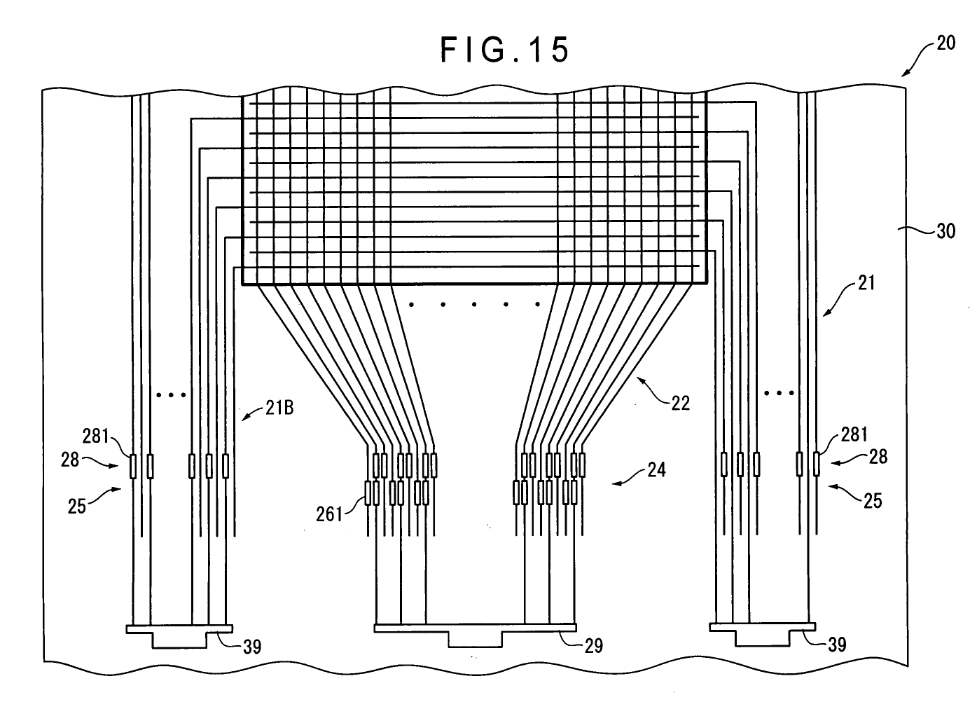

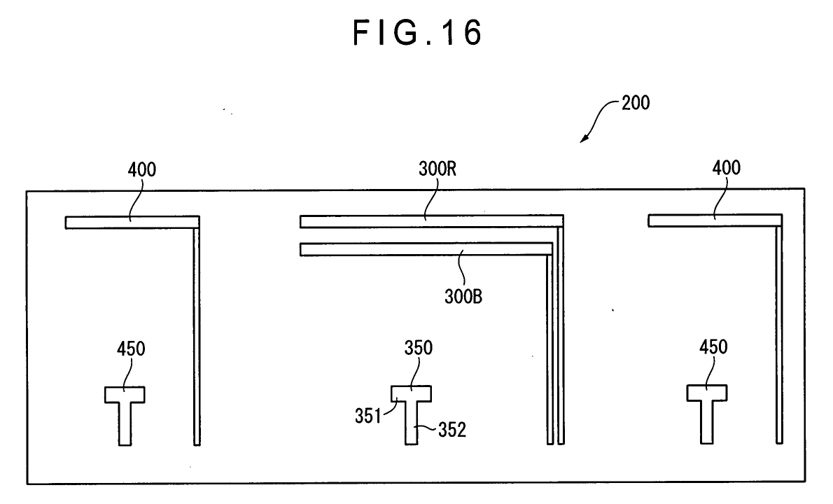

A sixth exemplary embodiment of the invention will be described with reference to the FIGS. 15 and 16.

Although basic arrangements of the sixth exemplary embodiment are similar to those of the fourth exemplary embodiment, the sixth exemplary embodiment has a feature that the drawing portion of the scanning lines also has the inspection terminal allocating layer and the line-connecting portion; and the inspection probe is provided with the wiring portion to be connected with the inspection terminal allocating layer of the scanning lines as well as the contact portion to be connected with the line-connecting portion of the scanning lines.

FIG. 15 shows an arrangement of the liquid crystal display panel 20 according to the sixth exemplary embodiment. FIG. 16 shows an arrangement of the inspection probe 200 of the sixth exemplary embodiment.

In FIG. 15, the drawing portion 24 of the data lines 22 is provided with the inspection terminal allocating layers 26R, 26B, and the green data lines 22G are drawn to be connected in the line-connecting portion 29.

The drawing portions 25 of the scanning lines 21 also have an inspection terminal allocating layer 28 and a line-connecting portion 39.

The scanning lines 21 are similar to those that are described in the third exemplary embodiment, and the inspection terminal allocating layers 28 is provided as stated above.

Specifically, in the inspection terminal allocating layer 28 of the scanning lines 21 in either of the drawing portions 25 on the right and left, an insulation covering 281 is provided to every two scanning lines, so that remaining every two scanning lines 21 are exposed as a signal input terminal.

In the inspection terminal allocating layer 28, the scanning lines 21 covered with the insulation covering 281 are drawn long such that the lower ends thereof are connected in the line-connecting portion 39.

FIG. 16 shows an arrangement of the inspection probe according to the sixth exemplary embodiment.

The basic arrangements of the inspection probe 200 of the sixth exemplary embodiment are similar to those of the fourth exemplary embodiment. However, in the sixth exemplary embodiment, the two wiring portions 300R, 300B and contact portion 350 that are connected with the data lines 22 are provided in a middle portion of the board 210, and the two wiring portions 400 for scanning lines and contact portions 450 that are connected with the scanning lines 21 are provided on each of the right and the left of the wiring portions 300R, 300B and contact portion 350. The arrangement of the wiring portion for scanning lines 400 is similar to that of the wiring portion 300R, 300B described in the fourth exemplary embodiment. Specifically, the wiring portion 300R, 300G, 300B is constituted of the main shaft section 310 and the coupling shaft section 320 and is provided with the communication wiring 330 and the bump 311. The contact portion 450 has an arrangement similar to that of the contact portion 350 described in the fourth exemplary embodiment, by which the contact portion 450 contacts the line-connecting portion 39 to establish continuity with the scanning lines 21 connected in the line-connecting portion 39.

In the arrangement, when connecting the inspection probe 200 to the liquid crystal display panel 20, the wiring portions 300R, 300B, 400 of the inspection probe 200 and the contact portions 350, 450 are pressed to the corresponding inspection terminal allocating layers 26, 28 and the line-connecting portions 29, 39. Thereby, the inspection probe 200 can be simultaneously connected with both of the data lines 22 and the scanning lines 21.

It should be noted that the invention is not limited to the above-described embodiments, and may be modified or improved as long as an object of the invention can be achieved.

In the inspection terminal allocating layer, the pitch in which the data lines and signal lines are covered with the insulating film is not particularly limited, but, of course, may be variously changed according to a desired precision of the image display inspection.

For example, the insulating film may be provided to every two signal lines (data lines, scanning lines) or every three signal lines. Obviously, the pitch of the signal lines being exposed as s signal input terminal may be variously changed based on a required precision of the image display inspection.

The above embodiments are explained using the liquid crystal display panel as an example. However, the invention can be applied to, for example, an electronics device such as a semiconductor, if the electronics device has a plurality of signal lines in which common inspection signals can be input in the inspection.

The optical panel (liquid crystal display panel) is explained using the liquid crystal display panel that displays an image in color by using R, G and B. However, it is obvious that the optical panel may be a liquid crystal display panel that displays an image black and white.

The invention can be applied to an image display inspection of optical panels and a characteristic inspection of electronics devices in which signal lines are wired.

What is claimed is:

1. An electronics device, comprising: a plurality of signal lines; and a drawing portion to which the plurality of signal lines are drawn to be disposed substantially in parallel with each other, wherein
the drawing portion has an inspection terminal allocating layer in which predetermined ones out of the signal lines are insulatively covered in a direction intersecting the drawing direction of the signal lines, while other predetermined ones out of the signal lines that are not insulatively covered are exposed as an inspection signal input terminal.

2. The electronics device according to claim 1, wherein
the inspection signal input terminal is a predetermined signal input terminal to which a common inspection signal can be input, and
predetermined signal lines to which the common inspection signal can be input out of the signal lines that are insulatively covered in the inspection terminal allocating layer are drawn longer than the other signal lines and connected in a line-connecting portion.

3. An optical panel having: columns of pixels exhibiting common one of basic colors, the columns of pixels exhibiting different basic colors being arranged in a row direction in a predetermined order so that more than one basic color are used to display a color image; and a drawing portion to which data lines provided to each column for actuating the pixels are drawn to be disposed substantially in parallel with each other, wherein
the drawing portion has an inspection terminal allocating layer in which predetermined data lines of a color other than a predetermined basic color are insulatively covered in a direction intersecting the drawing direction of the data lines, while data lines of the predetermined basic color that are not insulatively covered are exposed as an inspection signal input terminal.

4. The optical panel according to claim 3, wherein
the inspection terminal allocating layer is provided for each basic color in the drawing direction of the data lines.

5. The optical panel according to claim 3, wherein
the data lines being exposed as the signal input terminal is layered with an electric conductor in the inspection terminal allocating layer.

6. The optical panel according to claim 3, wherein
the data lines of at least one color other than the predetermined basic color are drawn longer than the other signal lines and connected in each line-connecting portion provided for each color.

7. An optical panel, comprising: scanning lines provided to each column for actuating pixels; and a drawing portion to which the scanning lines for actuating the pixels are drawn to be disposed substantially in parallel with each other, wherein
the drawing portion has an inspection terminal allocating layer in which predetermined ones out of the scanning lines are insulatively covered in a direction intersecting the drawing direction of the scanning lines, while other predetermined ones out of the scanning lines that are not insulatively covered are exposed as an inspection signal input terminal.

8. The optical panel according to claim 7, wherein
the inspection signal input terminal is a predetermined scanning line to which a common signal can be input, and
the predetermined scanning lines to which the common inspection signal can be input out of the scanning lines that are insulatively covered in the inspection terminal allocating layer are drawn longer than the other scanning lines and connected in a line-connecting portion.

9. An inspection probe being temporarily connected with a signal line in inspecting characteristics of an electronics device, wherein
the electronics device includes: a plurality of signal lines; and a drawing portion to which the plurality of signal lines are drawn to be disposed substantially in parallel with each other,
the drawing portion has an inspection terminal allocating layer in which predetermined ones out of the signal lines are insulatively covered in a direction intersecting the drawing direction of the signal lines, while other predetermined ones out of the signal lines that are not insulatively covered are exposed as an inspection signal input terminal,
the inspection probe, comprising:
a board; and
a wiring portion provided on the board, the wiring portion extending in a direction intersecting the drawing direction of the signal lines in correspondence with the inspection terminal allocating layer and contacting the inspection terminal allocating layer when being pressed on the signal lines from above so as to intersect the signal lines.

10. The inspection probe according to claim 9, wherein
the electronics device is a predetermined signal input terminal to which a common inspection signal can be input,
predetermined signal lines to which the common inspection signal can be input out of the signal lines that are insulatively covered in the inspection terminal allocating layer are drawn longer than the other signal lines and connected in a line-connecting portion, and
the inspection probe further, comprising:
a contact portion provided on the board, the contact portion contacting the line-connecting portion when being pressed on the signal lines from above such that the wiring portion contacts the signal input terminal.

11. An inspection probe being temporarily connected with a data line in inspecting image display of an optical panel, wherein
the optical panel includes: columns of pixels exhibiting common one of basic colors, the columns of pixels exhibiting different basic colors being arranged in a row direction in a predetermined order so that more than one basic color are used to display a color image; and a drawing portion to which data lines provided to each column for actuating the pixels are drawn to be disposed substantially in parallel with each other,
the drawing portion has an inspection terminal allocating layer in which predetermined data lines of a color other than a predetermined basic color are insulatively covered in a direction intersecting the drawing direction of the data lines, while data lines of the predetermined basic color that are not insulatively covered are exposed as an inspection signal input terminal,
the inspection probe, comprising:
a board; and
a wiring portion provided on the board, the wiring portion extending in a direction intersecting the drawing direction of the data lines in correspondence with the inspection terminal allocating layer and contacting the inspection terminal allocating layer when being pressed on the data lines from above so as to intersect the data lines.

12. An inspection probe being temporarily connected with a data line in inspecting image display of an optical panel, wherein
the optical panel includes: columns of pixels exhibiting common one of basic colors, the columns of pixels exhibiting different basic colors being arranged in a row direction in a predetermined order so that more than one basic color are used to display a color image; and a drawing portion to which data lines provided to each column for actuating the pixels are drawn to be disposed substantially in parallel with each other,
the drawing portion has an inspection terminal allocating layer in which predetermined data lines of a color other than a predetermined basic color are insulatively covered in a direction intersecting the drawing direction of the data lines, while data lines of the predetermined basic color that are not insulatively covered are exposed as an inspection signal input terminal,
the data lines of at least one color other than the predetermined basic color are drawn longer than the other data lines and connected in each line-connecting portion provided for each color,
the inspection probe, comprising:
a board,
a wiring portion provided on the board, the wiring portion extending in a direction intersecting the drawing direction of the data lines in correspondence with the inspection terminal allocating layer and contacting the inspection terminal allocating layer when being pressed on the data lines from above so as to intersect the data lines; and
a contact portion provided on the board, the contact portion contacting the line-connecting portion when being pressed on the data lines from above such that the wiring portion contact the inspection terminal allocating layer.

13. An inspection probe being temporarily connected with a scanning line in inspecting image display of an optical panel, wherein
the optical panel includes: scanning lines provided to each column for actuating pixels; and a drawing portion to which the scanning lines for actuating the pixels are drawn to be disposed substantially in parallel with each other,
the drawing portion has an inspection terminal allocating layer in which predetermined ones out of the scanning lines are insulatively covered in a direction intersecting the drawing direction of the scanning lines, while other predetermined ones out of the scanning lines that are not insulatively covered are exposed as an inspection signal input terminal,
the inspection probe, comprising:
a board; and
a wiring portion provided on the board, the wiring portion extending in a direction intersecting the drawing direction of the scanning lines in correspondence with the inspection terminal allocating layer and contacting the inspection terminal allocating layer when being pressed on the scanning lines from above so as to intersect the scanning lines.

14. An inspection probe being temporarily connected with a scanning line in inspecting image display of an optical panel according to claim 13, wherein
the optical panel includes: the inspection signal input terminal that is a predetermined scanning line to which a common signal can be input,
the predetermined scanning lines to which the common inspection signal can be input out of the scanning lines that are insulatively covered in the inspection terminal allocating layer and drawn longer than the other scanning lines and connected in a line-connecting portion,
the inspection probe, comprising:
a contact portion provided on the board, the contact portion contacting the line-connecting portion when being pressed on the scanning lines from above such that the wiring portion contacts the signal input terminal.

15. The inspection probe according to claim 9, wherein
the wiring portion has a communication wiring for transferring signals and a conductive resilient body covering the communication wiring.

16. An inspection device, comprising
an inspection probe; and
an inspection signal transmitter that inputs an inspection drive signal in an inspection signal input terminal via the inspection probe, wherein
the inspection probe is temporarily connected with a signal line in inspecting characteristics of an electronics device,
the inspection probe has: a board; and a wiring portion provided on the board, the wiring portion extending in a direction intersecting the drawing direction of the signal lines in correspondence with the inspection terminal allocating layer and contacting the signal input terminal when being pressed on the signal lines from above so as to intersect the signal lines, and
the electronics device has:
a plurality of signal lines and a drawing portion to which the plurality of signal lines are drawn to be disposed substantially in parallel with each other,
the drawing portion has an inspection terminal allocating layer in which predetermined ones out of the signal lines are insulatively covered in a direction intersecting the drawing direction of the signal lines, while other predetermined ones out of the signal lines that are not insulatively covered are exposed as an inspection signal input terminal.

17. An inspection method of an optical panel, comprising:
connecting of an inspection probe with the optical panel; and
signal-inputting of an inspection drive signal to the optical panel via the inspection probe, wherein
the inspection probe is temporarily connected with a signal line in inspecting characteristics of an electronics device,
the inspection probe has: a board and a wiring portion provided on the board, the wiring portion extending in a direction intersecting the drawing direction of the signal lines in correspondence with the inspection terminal allocating layer and contacting the signal input terminal when being pressed on the signal lines from above so as to intersect the signal lines, and
the electronics device has a plurality of signal lines and a drawing portion to which the plurality of signal lines are drawn to be disposed substantially in parallel with each other,
the drawing portion has an inspection terminal allocating layer in which predetermined ones out of the signal lines are insulatively covered in a direction intersecting the drawing direction of the signal lines, while other predetermined ones out of the signal lines that are not insulatively covered are exposed as an inspection signal input terminal.

18. The inspection method of the optical panel according to claim 17, the inspection method further comprising:
cutting-off for cutting off a line-connecting portion in the signal-inputting after the inspection of the optical panel is finished.
